(19) United States
(12) Patent Application Publication
(10) Pub. No.: US 2009/0288696 A1
(43) Pub. Date: Nov. 26, 2009

(54) Non-linear solar cell module

(75) Inventors: Sang-il Kim, Suwon-si (KR); Jong-hwa Won, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/385,193

(22) Filed: Apr. 1, 2009

(30) Foreign Application Priority Data
May 26, 2008 (KR) 10-2008-0048677

(51) Int. Cl. H01L 31/042; H01L 31/0256

(52) U.S. Cl. 136/244; 136/260; 257/E31.003

(57) ABSTRACT

Example embodiments provide a non-linear solar cell module. The non-linear solar cell module may include a plurality of photovoltaic cells. Each of the photovoltaic cells may comprise a lower electrode on a substrate, a photovoltaic conversion layer on the lower electrode, and an upper electrode formed on the photovoltaic conversion layer, and the photovoltaic cells may be in a non-linear shape.

### FOREIGN PRIORITY STATEMENT

This application claims priority under 35 U.S.C. §119 to Korean Patent Application No. 10-2008-0048677, filed on May 26, 2008 in the Korean Intellectual Property Office, the entire contents of which are incorporated herein by reference.

### BACKGROUND

1. Field

Example embodiments relate to a non-linear solar cell module, and for example, to a non-linear solar cell module in which the reduction of power generation due to a shadow or other obstruction may be decreased since photovoltaic cells of the solar cell module are formed in a non-linear shape.

2. Description of Related Art

A solar cell module may include a plurality of photovoltaic cells connected in series. Photovoltaic cells may be classified into a crystal type and a thin film type. Crystal type photovoltaic cells generally may have a rectangular shape, and may be formed of polysilicon. The rectangular shape crystal type photovoltaic cells may have shorter width and length and thus, when the rectangular shape crystal type photovoltaic cells are in the presence of a shadow or other obstruction, it is may be easier for one photovoltaic cell to be covered by the shadow or obstruction. Accordingly, the power generation of the solar cell modules may be reduced when a shadow or other obstruction appears on a photovoltaic cell.

Thin film type photovoltaic cells may have a rectangular shape with a length longer than that of the crystal type photovoltaic cells. Thus, the possibility of one film type photovoltaic cell being covered by a shadow or other obstruction is decreased. However, the power generation of the solar cell module that has the thin film type photovoltaic cells may still be reduced in the presence of a shadow or other obstruction.

### SUMMARY

Example embodiments provide a non-linear solar cell module that may diminish the reduction of power generation in the presence of a shadow or other obstruction.

According to an example embodiment, a solar cell module comprises a plurality of photovoltaic cells connected in series on a substrate, wherein each photovoltaic cell has a first dimension and a first sun coverage width, and the first sun coverage width of each photovoltaic cell is larger than the first dimension in a direction parallel to the first dimension.

According to an example embodiment, the first sun coverage width of each photovoltaic cell is approximately twice as large as the first dimension in a direction parallel to the first dimension.

According to an example embodiment, each photovoltaic cell has a wave shape.

According to an example embodiment, each photovoltaic cell has a plurality of bends, with each bend being approximately 90 degrees.

According to an example embodiment, each photovoltaic cell has a second dimension perpendicular to the first dimension a second sun coverage width, and a given starting point, and the second sun coverage width is greater than the second dimension in a direction parallel to the second dimension after at least one bend following the starting point.

According to an example embodiment, each photovoltaic cell has a serpentine shape.

According to an example embodiment, each photovoltaic cell has a second dimension perpendicular to the first dimension, a second sun coverage width, and a given starting point, and the second sun coverage width of each photovoltaic cell is equal to the second dimension in a direction parallel to the second dimension prior to a third bend following the starting point.

According to an example embodiment, each photovoltaic cell has a spiral shape.

According to an example embodiment, each photovoltaic cell occupies substantially the same area on the substrate.

According to an example embodiment, a photovoltaic cell comprises a lower electrode, a photovoltaic conversion layer on the lower electrode, and an upper electrode on the photovoltaic conversion layer, wherein the photovoltaic conversion layer has a first dimension and a first sun coverage width, and the first sun coverage width of the photovoltaic conversion layer is larger than the first dimension in a direction parallel to the first dimension.

According to an example embodiment, the first sun coverage width of the photovoltaic conversion layer is approximately twice as large as the first dimension in a direction parallel to the first dimension.

According to an example embodiment, the photovoltaic conversion layer has a wave shape.

According to an example embodiment, the photovoltaic conversion layer has a plurality of bends, with each bend being approximately 90 degrees.

According to an example embodiment, the photovoltaic conversion layer has a second dimension perpendicular to the first dimension, a second sun coverage width, and a given starting point, and the second sun coverage width is greater than the second dimension in a direction parallel to the second dimension after at least one bend following the starting point.

According to an example embodiment, the photovoltaic conversion layer has a serpentine shape.

According to an example embodiment, the photovoltaic conversion layer has a second dimension perpendicular to the first dimension, a second sun coverage width, and a given starting point, and the second sun coverage width of the photovoltaic conversion layer is equal to the second dimension in a direction parallel to the second dimension prior to a third bend following the starting point.

According to an example embodiment, the photovoltaic conversion layer has a spiral shape.

According to an example embodiment, the photovoltaic conversion layer comprises a first semiconductor layer and a second semiconductor layer to form a PN junction.

According to an example embodiment, the photovoltaic conversion layer further comprises an intrinsic semiconductor silicon layer to form a PIN junction.

According to an example embodiment, the photovoltaic conversion layer is one of amorphous silicon, CdTe, and Cu—In—Ga—Se.

### BRIEF DESCRIPTION OF THE DRAWINGS

The above and other features and advantages of example embodiments will become more apparent by describing them in detail with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a schematic plan view of a thin film type non-linear solar cell module according to example embodiments.

FIG. 2 is a cross-sectional view of a portion of the thin film type non-linear solar cell module of FIG. 1.

FIG. 3(a) is a conventional thin film type solar cell module covered by a shadow.

FIG. 3(b) is a thin film type non-linear solar cell module according to example embodiments and covered by a shadow that is substantially the same as the shadow shown in FIG. 3(a).

FIG. 4 is a schematic plan view of a non-linear solar cell module according to example embodiments.

FIG. 5 is a cross-sectional view of the non-linear solar cell module of FIG. 4.

FIG. 6 is a schematic plan view of a non-linear solar cell module according to example embodiments.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

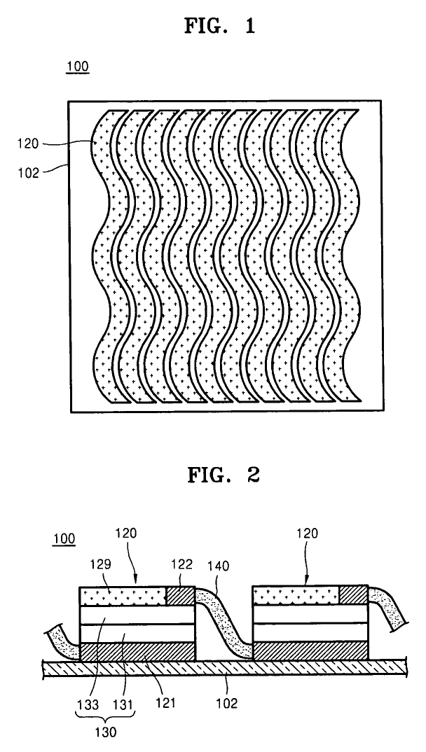

FIG. 1 is a schematic plan view of a thin film type non-linear solar cell module 100 according to example embodiments. FIG. 2 is a cross-sectional view of a portion of the thin film type non-linear solar cell module 100 of FIG. 1.

Referring to FIGS. 1 and 2, the thin film type non-linear solar cell module 100 may include a plurality of photovoltaic cells 120. The thin film type non-linear solar cell module 100 may include a few tens of photovoltaic cells 120, for example, and the photovoltaic cells 120 may be connected in series to obtain a given voltage.

Each of the photovoltaic cells 120 may include a lower electrode 121 formed on a substrate 102, a photovoltaic conversion layer 130 formed on the lower electrode 121, and an upper electrode 122 formed on the photovoltaic conversion layer 130. Two photovoltaic cells 120 may be electrically connected in series via a wire 140. For example, the wire 140 may connect the neighboring upper electrode 122 and the lower electrode 121 of the photovoltaic cells 120. Each of the photovoltaic cells 120 may occupy substantially the same area on the substrate 102.

The substrate 102 may be a silicon substrate, a glass substrate, or a substrate comprising one or more of silicon, glass, or other material.

The lower electrode 121 may be formed of an electrode material such as aluminum (Al).

The upper electrode 122 may be formed of an electrode material such as Al. Additionally, the upper electrode 122 may be formed of a transparent conductive material, that is, a transparent conductive oxide such as indium tin oxide (ITO). If the upper electrode 122 is formed of a transparent conductive material, sunlight may pass through the upper electrode 122.

An antireflection coating 129 may be formed on the photovoltaic conversion layer 130, except for the region where the upper electrode 122 is formed. Also, a protective layer (not shown in FIGS. 1 and 2) that covers the upper electrode 122, such as an epoxy layer or a glass layer, may be formed on the upper electrode 122.

The photovoltaic conversion layer 130 may generate electron-hole pairs in response to sunlight, and electrons and holes of the electron-hole pairs may separate and move towards the upper electrode 122 and the lower electrode 121, respectively. Thus, a photoelectric current may be generated between the outermost upper electrode 122 and the lower electrode 121.

The photovoltaic conversion layer 130 may have a PN junction structure, and may include a first semiconductor layer 131 formed of an n-type or p-type semiconductor material and a second semiconductor layer 133 formed of a p-type or an n-type semiconductor material. The first and second semiconductor layers 131 and 133 may be formed of amorphous silicon, CdTe, or Cu—In—Ga—Se (CIGS), for example.

Example embodiments are not limited to the above materials and stacking structure of the photovoltaic conversion layer 130. For clarity, various well-known processes and elements, which may be essential for manufacturing conventional solar cells, are not described.

Example embodiments provide that an intrinsic semiconductor layer may be interposed between the first and second semiconductor layers 131 and 133 and a PIN junction structure may be formed. The intrinsic semiconductor layer may be an intrinsic semiconductor silicon layer, for example.

In FIG. 1, spaces above the substrate 102 may be filled with an insulating material, but for clarity this insulating material is not depicted.

FIG. 2 shows the upper electrode 122 covering a portion of the photovoltaic conversion layer 130, however example embodiment are not limited thereto. The upper electrode 122 may be formed as a plurality of wires (not shown in FIG. 2) on the photovoltaic conversion layer 130, for example.

At least one component of each of the photovoltaic cells 120 may have a non-linear shape, for example, a wave shape as shown in FIG. 1.

Although any component of the photovoltaic cells, such as the photovoltaic conversion layer, or any group of components of the photovoltaic cells, may have a non-linear shape, however, for clarity only example embodiments where all components of the photovoltaic cells have non-linear shapes will be illustrated in the drawings.

The wave shaped photovoltaic cells 120 shown in FIG. 1 may diminish the reduction of power generation if a shadow or other obstruction crosses over the photovoltaic cells 120. Thus, the power generation of the wave shaped photovoltaic cells 120 may be greater than the power generation of the photovoltaic cells of a conventional rectangular shape thin film type solar cell in the presence of a shadow or other obstruction.

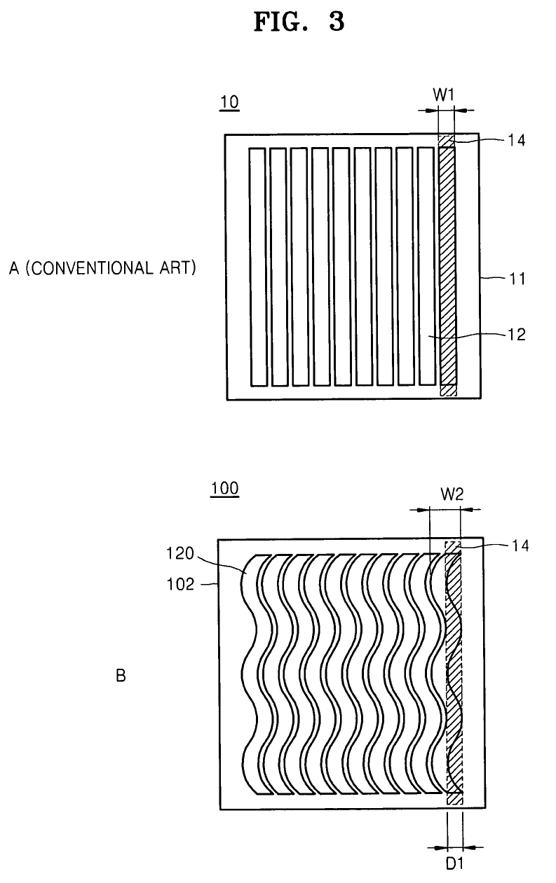

FIG. 3(a) shows a conventional thin film type solar cell module 10 covered by a shadow 14 and FIG. 3(b) shows the thin film type non-linear solar cell module 100 according to example embodiments and covered by substantially the same shadow 14 as shown in FIG. 3(a).

The conventional thin film type solar cell module 10 of FIG. 3(a) may include a plurality of photovoltaic cells 12 connected in series. Each photovoltaic cell 12 may have a sun coverage width W1. The sun coverage width W1 illustrates the size of the shadow 14 required to completely cover a photovoltaic cell 12 and prevent the generation of power.

FIG. 3(a) illustrates that one of the photovoltaic cells 12 may be completely covered by the shadow 14, and accordingly the sun coverage width W1 of the photovoltaic cell 12 may be completely covered by the shadow 14 and may not generate any power. Thus, the conventional thin film type solar cell module 10 covered by the shadow 14 may not generate any power.

As shown in FIG. 3(b), each photovoltaic cell 120 may have a first sun coverage width W2 and a first dimension D1. The first dimension D1 shown in FIG. 3(b) illustrates a given area of the photovoltaic cells 12, and the first sun coverage width W2 illustrates the size of the shadow or other obstruction required to completely cover a photovoltaic cell 120 and prevent the generation of power by the photovoltaic cell 120.

It should be noted that the first dimension D1 illustrates an example embodiment of a dimension, and other example embodiments of dimensions may vary in size and shape without limitation, and may have an area including one or more photovoltaic cells. It should further be noted that the first sun coverage width W2 is an example embodiment illustrating the sun coverage width of each photovoltaic cell 120, and other example embodiments of photovoltaic cells having varying sizes and shapes may have sun coverage widths of varying sizes and shapes.

FIG. 3(b) illustrates an example embodiment where the first sun coverage width W2 may be larger than the first dimension D1 in a direction parallel to the first dimension D1, and for example may be twice as large. As shown in FIG. 3(b), each photovoltaic cell 120 may have a wave shape. Additionally, any component of a photovoltaic cell 120, such as the photovoltaic conversion layer 130 as shown in FIG. 2, may have such a shape.

The thin film type non-linear solar cell module 100 of FIG. 3(b) has the first sun coverage width W2, which may be approximately twice as large as the sun coverage width W1 of the conventional thin film type solar cell module 10. Accordingly, although the substantially the same shadow 14 as shown in FIG. 3(a) covers the thin film type non-linear solar cell module 100, the thin film type non-linear solar cell module 100 may generate more power than the conventional thin film type solar cell module 10. The thin film type non-linear solar cell module 100 may generate approximately 50% of the power generated in the absence of shadows or other obstructions, for example.

Example embodiments of the photovoltaic cells 120 of the thin film type non-linear solar cell module 100 may be formed by etching the lower electrode 121, the photovoltaic conversion layer 130, and the upper electrode 122 using a laser or using a semiconductor manufacturing process even though the photovoltaic cells 120 may have a non-linear shape.

Although the non-linear solar cell module 100 shown in FIG. 1 is a thin film type, example embodiments are not limited thereto. For example, photovoltaic cells of a crystal type polysilicon solar cell module may also be formed in a non-linear shape.

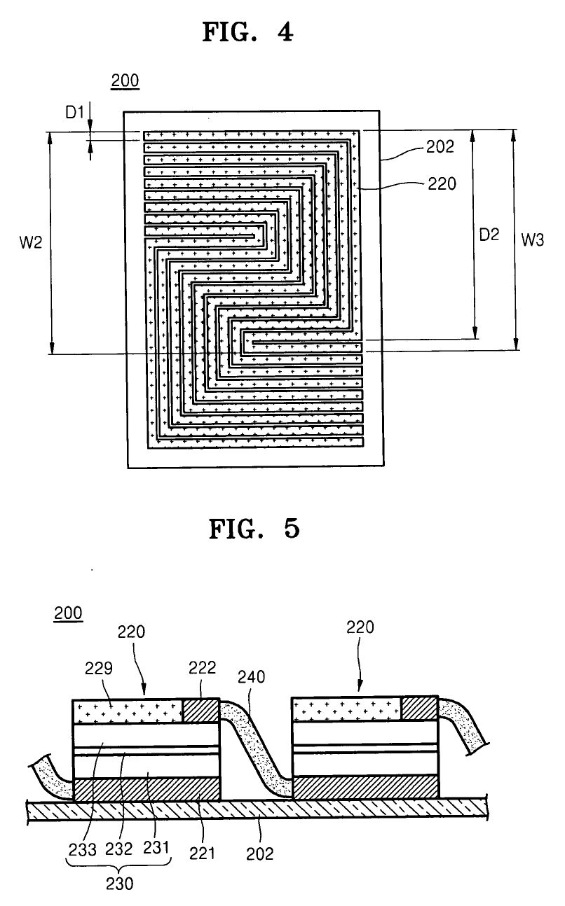

FIG. 4 is a schematic plan view of a non-linear solar cell module 200 according to example embodiments. FIG. 5 is a cross-sectional view of the non-linear solar cell module 200 of FIG. 4. Referring to FIGS. 4 and 5, the non-linear solar cell module 200 may include a plurality of photovoltaic cells 220. The non-linear solar cell module 200 may include a few tens of photovoltaic cells 220, for example, and the photovoltaic cells 220 may be connected in series to obtain a given voltage.

Each of the photovoltaic cells 220 may include a lower electrode 221 formed on a substrate 202, a photovoltaic conversion layer 230 formed on the lower electrode 221, and an upper electrode 222 formed on the photovoltaic conversion layer 230. Two photovoltaic cells 220 may be electrically connected in series via a wire 240. Each of the photovoltaic cells 220 may occupy substantially the same area on the substrate 202.

The photovoltaic conversion layer 230 may have a PN junction structure, and may include a first semiconductor layer 231 formed of an n-type or p-type semiconductor material, an intrinsic semiconductor silicon layer 232, and a second semiconductor layer 233 formed of a p-type or an n-type semiconductor material.

An antireflection coating 229 may be formed on the photovoltaic conversion layer 230, except for the region where the upper electrode 222 is formed. Also, a protective layer (not shown in FIGS. 4 and 5) that covers the upper electrode 222, for example, an epoxy layer or a glass layer, may be formed.

As shown in FIG. 4, example embodiments provide that each photovoltaic cell 220 may have a first dimension D1, a second dimension D2 that is perpendicular to the first dimension D1, a first sun coverage width W2, and a second sun coverage width W3. As shown in FIG. 4, the photovoltaic cells 220 may have a serpentine shape. Additionally, any component of a photovoltaic cell 220, such as a photovoltaic conversion layer 230 as shown in FIG. 5, may have such a shape.

The serpentine shape example embodiment of FIG. 4, may include a given starting point. For example, the starting point may be in a top left corner of the photovoltaic cells 220 illustrated in FIG. 4, or in a bottom right corner of the photovoltaic cells 220 illustrated in FIG. 4. Following the formation of at least one bend in the photovoltaic cells 220 after the starting point, the second sun coverage width W3 may be greater than the second dimension D2 in a direction parallel to the second dimension D2.

It should be noted that example embodiments of photovoltaic cells may include one or more starting points, that the location of starting points may vary, and that the location of starting points may correspond to the location of other starting points or to the particular configuration of the photovoltaic cells.

Example embodiments of the photovoltaic cells 220 may have a serpentine shape. Each one of the photovoltaic cells 220 having a serpentine shape is formed to have an increased coverage over the substrate 202 compared to the photovoltaic cell 12 of the conventional rectangular shape thin film type solar cell module 10 and the photovoltaic cell 120 of the thin film type non-linear solar cell module 100. Thus, the photovoltaic cells 220 having a serpentine shape may diminish the reduction of power generation due to a shadow or other obstruction.

The bends of the photovoltaic cells 220 may be formed at approximately 90 degrees, and thus, the region occupied by each photovoltaic cell 220 on the substrate 202 may be increased.

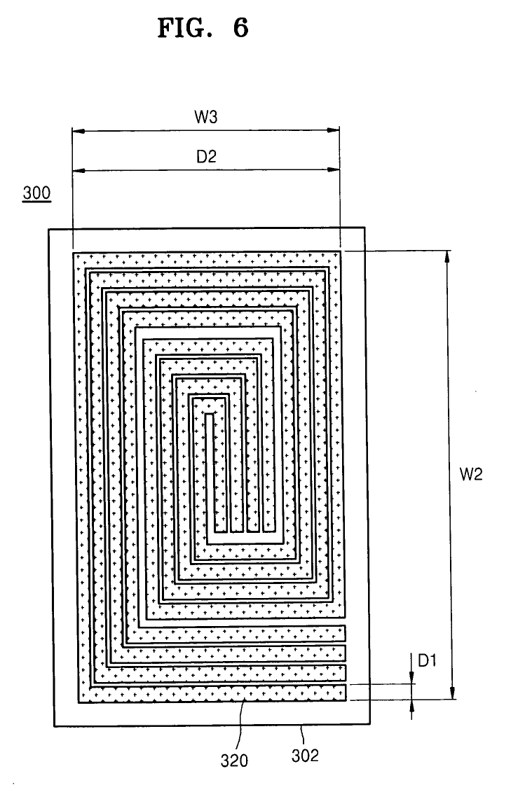

FIG. 6 is a schematic plan view of a non-linear solar cell module 300 according to example embodiments. Referring to FIG. 6, the non-linear solar cell module 300 may include a plurality of photovoltaic cells 320. The non-linear solar cell module 300 may include a few tens of photovoltaic cells 320, for example, and the photovoltaic cells 320 may be connected in series to obtain a given voltage.

As shown in FIG. 6. example embodiments provide that each photovoltaic cell 320 may have a first dimension D1, a second dimension D2 that is perpendicular to the first dimension D1, a first sun coverage width W2, and a second sun coverage width W3. The second sun coverage width W3 may be equal to the second dimension D2 in a direction parallel to the second dimension D2 prior to a third bend. As shown in FIG. 6, the photovoltaic cells 320 may have a spiral shape. Additionally, any component of a photovoltaic cell 320, such as a photovoltaic conversion layer 130 or 230 as shown in FIGS. 2 and 5, may have such a shape.

The spiral shape example embodiment of FIG. 6 may include a given starting point. For example, the starting point may be in a bottom right corner of the photovoltaic cells 320 illustrated in FIG. 6, or in the opposite, somewhat centrally located corner of the photovoltaic cells 320 illustrated in FIG. 6.

Example embodiments of the photovoltaic cells 320 of FIG. 6 may be substantially the same as example embodiments of photovoltaic cells 120 and 220 shown FIGS. 2 and 5, and for clarity the description will not be repeated.

The photovoltaic cells 320 may have a spiral shape on a substrate 302. Each of the photovoltaic cells 320 having a spiral shape may be formed to have an increased coverage over the substrate 302, and thus the possibility of being totally covered by a shadow or other obstruction may be decreased, thereby diminishing the reduction of power generation due to a shadow or other obstruction.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A solar cell module comprising:
a plurality of photovoltaic cells connected in series on a substrate, wherein each photovoltaic cell has a first dimension and a first sun coverage width, and
the first sun coverage width of each photovoltaic cell is larger than the first dimension in a direction parallel to the first dimension.

2. The solar cell module of claim 1, wherein
the first sun coverage width of each photovoltaic cell is approximately twice as large as the first dimension in a direction parallel to the first dimension.

3. The solar cell module of claim 1, wherein
each photovoltaic cell has a wave shape.

4. The solar cell module of claim 1, wherein
each photovoltaic cell has a plurality of bends, with each bend being approximately 90 degrees.

5. The solar cell module of claim 4, wherein
each photovoltaic cell has a second dimension perpendicular to the first dimension, a second sun coverage width, and a given starting point, and
the second sun coverage width is greater than the second dimension in a direction parallel to the second dimension after at least one bend following the starting point.

6. The solar cell module of claim 5, wherein
each photovoltaic cell has a serpentine shape.

7. The solar cell module of claim 4, wherein
each photovoltaic cell has a second dimension perpendicular to the first dimension, a second sun coverage width, and a given starting point, and
the second sun coverage width of each photovoltaic cell is equal to the second dimension in a direction parallel to the second dimension prior to a third bend following the starting point.

8. The solar cell module of claim 7, wherein
each photovoltaic cell has a spiral shape.

9. The solar cell module of claim 1, wherein
each photovoltaic cell occupies substantially the same area on the substrate.

10. A photovoltaic cell comprising:
a lower electrode,
a photovoltaic conversion layer on the lower electrode, and
an upper electrode on the photovoltaic conversion layer, wherein
the photovoltaic conversion layer has a first dimension and a first sun coverage width, and
the first sun coverage width of the photovoltaic conversion layer is larger than the first dimension in a direction parallel to the first dimension.

11. The photovoltaic cell of claim 10, wherein
the first sun coverage width of the photovoltaic conversion layer is approximately twice as large as the first dimension in a direction parallel to the first dimension.

12. The photovoltaic cell of claim 10, wherein
the photovoltaic conversion layer has a wave shape.

13. The photovoltaic cell of claim 10, wherein
the photovoltaic conversion layer has a plurality of bends, with each bend being approximately 90 degrees.

14. The photovoltaic cell of claim 13, wherein
the photovoltaic conversion layer has a second dimension perpendicular to the first dimension, a second sun coverage width, and a given starting point, and
the second sun coverage width is greater than the second dimension in a direction parallel to the second dimension after at least one bend following the starting point.

15. The photovoltaic cell of claim 14, wherein
the photovoltaic conversion layer has a serpentine shape.

16. The photovoltaic cell of claim 13, wherein
the photovoltaic conversion layer has a second dimension perpendicular to the first dimension, a second sun coverage width, and a given starting point, and
the second sun coverage width of the photovoltaic conversion layer is equal to the second dimension in a direction parallel to the second dimension prior to a third bend following the starting point.

17. The photovoltaic cell of claim 16, wherein
the photovoltaic conversion layer has a spiral shape.

18. The photovoltaic cell of claim 10, wherein
the photovoltaic conversion layer comprises a first semiconductor layer and a second semiconductor layer to form a PN junction.

19. The photovoltaic cell of claim 18, wherein
the photovoltaic conversion layer further comprises an intrinsic semiconductor silicon layer to form a PIN junction.

20. The photovoltaic cell of claim 10, wherein
the photovoltaic conversion layer is one of amorphous silicon, CdTe, and Cu—In—Ga—Se.
